(19) United States
(12) Patent Application Publication
(10) Pub. No.: US 2025/0239559 A1
(43) Pub. Date: Jul. 24, 2025

(54) SEMICONDUCTOR DEVICE

(71) Applicant: Mitsubishi Electric Corporation, Tokyo (JP)

(72) Inventor: Takashi TSUBAKIDANI, Tokyo (JP)

(73) Assignee: Mitsubishi Electric Corporation, Tokyo (JP)

(21) Appl. No.: 18/981,399

(22) Filed: Dec. 13, 2024

(30) Foreign Application Priority Data
Jan. 24, 2024 (JP) 2024-008855

(51) Int. Cl. H01L 23/00; H01L 23/495

(52) U.S. Cl. CPC H01L 24/48; H01L 23/49503; H01L 23/49575; H01L 24/49; H01L 2224/48108; H01L 2224/48137; H01L 2224/48245; H01L 2224/49109; H01L 2224/49177

(57) ABSTRACT

A semiconductor device includes at least three first die pads, at least three first semiconductor elements individually mounted on the first die pads, a first wire electrically connecting each of the first semiconductor elements, at least three second die pads arranged alternately with the first die pads, at least three second semiconductor elements individually mounted on the second die pads, and a second wire electrically connecting each of the second semiconductor elements.

### BACKGROUND OF THE INVENTION

### Field of the Invention

The present disclosure relates to a semiconductor device.

### Description of the Background Art

Conventionally, as a semiconductor device in which a plurality of semiconductor elements and a control integrated circuit are mounted in one package, a semiconductor device in which a plurality of semiconductor elements are mounted on one die pad is known. For example, in Japanese Patent Application Laid-Open No. 2009-111154, a plurality of sets of pairs of an IGBT chip and a freewheel diode, which are semiconductor elements, are mounted on one die pad portion of a lead frame. Specifically, three sets of the IGBT chip and the freewheel diode on a high potential side are mounted on one die pad portion, and three sets of the IGBT chip and the freewheel diode on a low potential side are mounted on three die pad portions. The IGBT chip and the freewheel diode are electrically connected to a predetermined lead frame by a bonding wire.

In the device of Japanese Patent Application Laid-Open No. 2009-111154, three sets of the IGBT chip and the freewheel diode on the high potential side are mounted on one die pad portion. Therefore, the semiconductor element on the high potential side and the semiconductor element on the low potential side, which need to be electrically connected to each other, are arranged at positions separated from each other. Therefore, a lead terminal connected to the die pad portion mounted with the semiconductor element on the low potential side is bent and arranged so as to approach in a direction in which the semiconductor element on the high potential side is present, and the semiconductor element on the high potential side and the semiconductor element on the low potential side are electrically connected by wire bonding using the bent portion of the lead terminal.

Therefore, in the device of Japanese Patent Application Laid-Open No. 2009-111154, since a space for arranging the bent lead terminal is required, an area of the die pad portion with respect to an area of the entire device has been unable to be enlarged by the space for arranging the bent lead terminal, and there has been a problem of being unable to improve heat dissipation of the semiconductor element by enlarging the area of the die pad portion.

### SUMMARY

The present disclosure has been made to solve the above-described problems, and an object of the present disclosure is to provide a semiconductor device capable of enlarging an area of a die pad with respect to a device area as compared with a conventional semiconductor device, and improving heat dissipation.

A semiconductor device according to the present disclosure includes: at least three first die pads; at least three first semiconductor elements individually mounted on the first die pads; a first wire electrically connecting each of the first semiconductor elements; at least three second die pads arranged alternately with the first die pads; at least three second semiconductor elements individually mounted on the second die pads; and a second wire electrically connecting each of the second semiconductor elements.

According to the semiconductor device of the present disclosure, it is possible to enlarge an area of a die pad with respect to a device area, thereby improving heat dissipation.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a semiconductor device according to a first preferred embodiment of the present disclosure;

FIG. 2 is a cross-sectional view illustrating the semiconductor device according to the first preferred embodiment of the present disclosure;

FIG. 3 is a plan view illustrating a semiconductor device according to a second preferred embodiment of the present disclosure;

FIGS. 4 and 5 are cross-sectional views each illustrating the semiconductor device according to the second preferred embodiment of the present disclosure;

FIG. 6 is a plan view illustrating a semiconductor device according to a third preferred embodiment of the present disclosure;

FIG. 7 is a plan view illustrating a semiconductor device according to a fourth preferred embodiment of the present disclosure; and

FIG. 8 is a plan view illustrating a semiconductor device according to a fifth preferred embodiment of the present disclosure.

### DESCRIPTION OF THE PREFERRED EMBODIMENTS

Hereinafter, an example of a semiconductor device according to the present disclosure will be described with reference to the drawings. In the drawings, the same or corresponding parts are denoted by the same reference numerals, and the description thereof will not be repeated.

In the present specification, a semiconductor device including a three-phase inverter circuit will be described as an example of a semiconductor device in which a plurality of semiconductor elements and a control integrated circuit are mounted in one package. Here, the three-phase inverter circuit is a circuit that converts DC power into three-phase (U-phase, V-phase, W-phase) AC power.

### First Preferred Embodiment

A first preferred embodiment of the present disclosure relates to a semiconductor device 101 including: at least three first die pads; at least three first semiconductor elements individually mounted on the first die pads; a first wire electrically connecting each of the first semiconductor elements; at least three second die pads arranged alternately with the first die pads; at least three second semiconductor elements individually mounted on the second die pads; and a second wire electrically connecting each of the second semiconductor elements.

### Configuration of First Preferred Embodiment

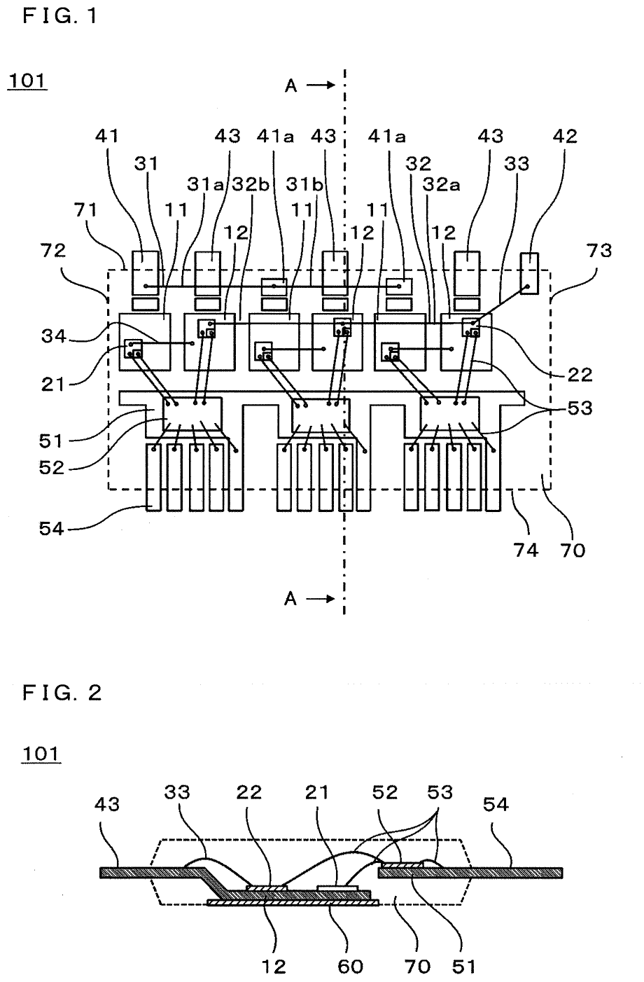

A configuration of the semiconductor device 101 according to the first preferred embodiment of the present disclosure will be described with reference to FIGS. 1 and 2. FIG. 1 is a plan view illustrating the semiconductor device 101, and FIG. 2 is a cross-sectional view taken along line A-A in FIG. 1. In FIGS. 1 and 2, a sealing resin 70 is omitted in order to show a structure inside the sealing resin 70. In FIGS. 1 and 2, an outline when the sealing resin 70 is present is indicated by a dotted line.

As illustrated in FIGS. 1 and 2, inside the sealing resin 70 having a quadrangular plan view shape, the semiconductor device 101 includes a die pad (11, 12, 51), a semiconductor element (21, 22), a control integrated circuit 52, a wire (31, 32, 33, 34, 53), a terminal (41, 42, 43, 54), and an insulating sheet 60. In sealing, a part of the terminal (41, 42, 43, 54) and at least a part of a lower surface of the insulating sheet 60 are exposed to the outside of the sealing resin 70. Hereinafter, details of each configuration will be described.

The semiconductor device 101 includes three first die pads 11 and three second die pads 12. The three first die pads 11 and the three second die pads 12 have a quadrangular plan view shape, and are alternately arranged. Specifically, the three first die pads 11 and the three second die pads 12 are alternately arranged along an extending direction of a first side 71 of the sealing resin 70 having a quadrangular plan view shape in plan view. In other words, in plan view, the first side 71 of the sealing resin 70 is a side extending in a direction in which the first die pad 11 and the second die pad 12 are alternately arranged.

FIG. 1 illustrates an example in which, among sides of the sealing resin 70 in plan view, the first side 71 is a side extending in the direction in which the first die pad 11 and the second die pad 12 are alternately arranged, and the first side 71 is a long side of the sealing resin 70 in plan view. However, it suffices to alternately arrange the first die pad 11 and the second die pad 12 along a direction of one of the four sides of the sealing resin 70 in plan view. That is, regarding the first die pad 11 and the second die pad 12 in FIG. 1, the three first die pads 11 and the three second die pads 12 may be arranged along one short side (a second side 72 or a third side 73 in FIG. 1) of the sealing resin 70, for example.

The first die pad 11 and the second die pad 12 are plate-shaped members each having an upper surface and a lower surface. A material having conductivity and good thermal conductivity, such as copper, is used for the first die pad 11 and the second die pad 12.

On the upper surfaces of the three first die pads 11, three first semiconductor elements 21 are individually mounted. Further, on the upper surfaces of the three second die pads 12, three second semiconductor elements 22 are individually mounted.

The first semiconductor element 21 and the second semiconductor element 22 are components for constituting a three-phase inverter circuit that converts DC power into three-phase (U-phase, V-phase, W-phase) AC power, and are elements that perform a switching operation. The first semiconductor element 21 is electrically connected between a first main terminal 41 to be described later and an output terminal 43 to be described later, in order to constitute the above-described three-phase inverter circuit. In addition, the second semiconductor element 22 is connected between the output terminal 43 to be described later and a second main terminal 42 to be described later, in order to constitute the above-described three-phase inverter circuit. Then, the first semiconductor element 21 is connected to an external substrate (not illustrated) on a high potential side of DC power in the three-phase inverter circuit. The second semiconductor element 22 is connected to an external substrate (not illustrated) on a low potential side of DC power in the three-phase inverter circuit. In other words, a relatively high potential is supplied to the first semiconductor element 21 as compared with the second semiconductor element 22. A relatively low potential is supplied to the second semiconductor element 22 as compared with the first semiconductor element 21.

The first semiconductor element 21 and the second semiconductor element 22 are, for example, a reverse conducting (RC)-insulated gate bipolar transistor (IGBT). The RC-IGBT is an element including an IGBT and a freewheel diode in one chip, and performs both a switching operation and a reflux operation. Note that, it suffices that the first semiconductor element 21 and the second semiconductor element 22 are able to perform the switching operation, and a combination of two or more elements may be used as the first semiconductor element 21 and the second semiconductor element 22. That is, a combination of a switching element and a diode connected in anti-parallel may be used as the first semiconductor element 21 or the second semiconductor element 22. For example, an IGBT or a metal oxide semiconductor (MOS) transistor may be combined with a freewheel diode, to be used as the first semiconductor element 21 or the second semiconductor element 22.

Three first semiconductor elements 21 and three second semiconductor elements 22 are provided corresponding to three-phase AC power to be output. A configuration of the three-phase inverter circuit including the first semiconductor element 21 and the second semiconductor element 22 will be described later.

The semiconductor device 101 includes the first main terminal 41, the second main terminal 42, and three output terminals 43. Among the three first die pads 11, the first main terminal 41 extends from the first die pad 11 arranged on one end side in the direction in which the first die pad 11 and the second die pad 12 are alternately arranged. The second main terminal 42 is arranged on another end side in the direction in which the first die pad 11 and the second die pad 12 are alternately arranged. Here, in FIG. 1, one end side in the direction in which the first die pad 11 and the second die pad 12 are alternately arranged is a left end side, and another end side in the direction in which the first die pad 11 and the second die pad 12 are alternately arranged is a right end side. Three of the output terminals extend from at least three of the second die pads.

The first main terminal 41, the second main terminal 42, and the output terminal 43 protrude to outside from a first side surface including the first side 71 in the sealing resin 70. The first side 71 is a side extending in the direction in which the first die pad 11 and the second die pad 12 are alternately arranged among sides of the sealing resin 70 in plan view.

Note that FIG. 1 illustrates an example in which the first side 71 included in the first side surface of the sealing resin 70 is a long side of the sealing resin 70 in plan view, but it suffices that the first side surface is a side surface including one of four sides of the sealing resin 70 having a quadrangular plan view shape. That is, the first side surface may be a side surface including a short side (the second side 72 or the third side 73 in FIG. 1) of the sealing resin 70 in plan view. As illustrated in FIG. 1, in a case where the first side 71 included in the first side surface of the sealing resin 70 is a long side of the sealing resin 70 in plan view, as compared with a case of a short side, the first main terminal 41, the second main terminal 42, and the output terminal 43 are arranged away from one another. Thus, a creepage distance between the terminals can be reliably secured.

Although FIG. 1 illustrates an example in which portions protruding from the sealing resin 70 in the first main terminal 41, the second main terminal 42, and the output terminal 43 have a quadrangular plan view shape, the present disclosure is not limited thereto. The portions protruding from the sealing resin 70 in the first main terminal 41, the second main terminal 42, and the output terminal 43 may be, for example, a plate-shaped member having a polygonal shape or a rounded shape.

The first main terminal 41 and the second main terminal 42 are electrically connected to an external substrate (not illustrated), and are provided for inputting DC power. The output terminal 43 is electrically connected to an external substrate (not illustrated), and is provided for outputting AC power. Similarly to the first die pad 11 and the second die pad 12, the first main terminal 41, the second main terminal 42, and the output terminal 43 contain a material having conductivity and good thermal conductivity, such as, for example, copper.

As illustrated in FIG. 1, the semiconductor device 101 may include an inner lead 41a that extends from two first die pads 11 among the three first die pads 11 and is entirely sealed inside the sealing resin 70. Specifically, the inner lead 41a extends from two first die pads 11 arranged on another end side in the direction in which the first die pad 11 and the second die pad 12 are alternately arranged. The inner lead 41a is a member extending from the first die pad 11, but does not protrude to the outside of the sealing resin 70 unlike the first main terminal 41. The inner lead 41a is formed for electrical connection inside the semiconductor device 101.

The semiconductor device 101 includes a plurality of wires for electrically connecting the three first semiconductor elements 21 and the three second semiconductor elements 22. Specifically, the semiconductor device 101 includes a first wire 31, a second wire 32, a third wire 33, and a fourth wire 34.

The first wire 31 is a wire that electrically connects each of the three first semiconductor elements 21, and is provided to connect between two first die pads 11 adjacent to each other with the second die pad 12 interposed in between. Specifically, the first wire 31 includes: a first wire 31a provided to connect between two first die pads 11 on one end side in the direction in which the first die pad 11 and the second die pad 12 are alternately arranged; and a first wire 31b provided to connect between two first die pads 11 on another end side in the direction in which the first die pad 11 and the second die pad 12 are alternately arranged. Here, the two first die pads 11 on one end side are two first die pads 11 arranged on the left end side in FIG. 1, and the two first die pads 11 on another end side are two first die pads 11 arranged on the right end side in FIG. 1. That is, the first wire 31 is a general term for wires provided to connect between the first die pads 11. The first wire 31 may be configured using a plurality of wires, or may be provided to connect by one wire.

The second wire 32 is a wire that electrically connects each of the three second semiconductor elements 22, and is provided to connect between two second semiconductor elements 22 mounted on two second die pads 12 adjacent to each other with the first die pad 11 interposed in between. Specifically, the second wire 32 includes: a second wire 32a provided to connect between two second semiconductor elements 22 on another end side in the direction in which the first die pad 11 and the second die pad 12 are alternately arranged; and a second wire 32b provided to connect between two second semiconductor elements 22 on one end side in the direction in which the first die pad 11 and the second die pad 12 are alternately arranged. Here, the two second semiconductor elements 22 on one end side are two second semiconductor elements 22 arranged on the left end side in FIG. 1, and the two second semiconductor elements 22 on another end side are two second semiconductor elements 22 arranged on the right end side in FIG. 1. That is, the second wire 32 is a general term for wires provided to connect between the second semiconductor elements 22. The second wire 32 may be configured using a plurality of wires, or may be provided to connect by one wire.

The third wire 33 is a wire that electrically connects the second main terminal 42 and the second semiconductor element 22. The third wire 33 is provided to connect between the second main terminal 42 and the second semiconductor element 22 arranged on another end side in the direction in which the first die pad 11 and the second die pad 12 are alternately arranged.

The fourth wire 34 is a wire that electrically connects the first semiconductor element 21 and the second semiconductor element 22, and is provided to connect between the first semiconductor element 21 and the second die pad 12 adjacent to each other.

As the first wire 31, the second wire 32, the third wire 33, and the fourth wire 34, for example, a bonding wire containing an aluminum wire is used.

In addition, the semiconductor device 101 includes three control integrated circuits 52 for controlling the first semiconductor element 21 and the second semiconductor element 22. Specifically, in response to an operation command from the outside, the control integrated circuit 52 generates and outputs control signals for the first semiconductor element 21 and the second semiconductor element 22. Each of the three control integrated circuits 52 is mounted on an upper surface of one third die pad 51.

Although FIGS. 1 and 2 illustrate an example in which the three control integrated circuits 52 are provided, the control integrated circuit 52 is not limited thereto, and for example, two control integrated circuits 52 may be provided.

In addition, the semiconductor device 101 includes a plurality of control terminals 54 electrically connected to the control integrated circuit 52. The control terminal 54 protrudes to the outside of the sealing resin 70 from a fourth side surface including a fourth side 74 opposite to the first side 71 of the sealing resin 70 in plan view. The plurality of control terminals 54 are electrically connected to an external substrate (not illustrated), and are provided to receive operation commands to the first semiconductor element 21 and the second semiconductor element 22.

The semiconductor device 101 further includes a plurality of fifth wires 53 provided to connect between the first semiconductor element 21 and the control integrated circuit 52, between the second semiconductor element 22 and the control integrated circuit 52, and between the control terminal 54 and the control integrated circuit 52. For example, the plurality of fifth wires 53 are provided for the control integrated circuit 52 to transmit a control signal instructing ON or OFF in the switching operation to the first semiconductor element 21 and the second semiconductor element 22, or for the control integrated circuit 52 to receive operation commands to the first semiconductor element 21 and the second semiconductor element 22 from the outside. As the fifth wire 53, for example, a bonding wire made by a gold wire is used.

Further, the semiconductor device 101 includes the insulating sheet 60 as illustrated in FIG. 2. The insulating sheet 60 is arranged such that an upper surface of the insulating sheet 60 faces the lower surfaces of the first die pad 11 and the second die pad 12, that is, surfaces of the first die pad 11 and the second die pad opposite to mounting surfaces of the first semiconductor element 21 and the second semiconductor element 22.

For the insulating sheet 60, a material having insulating properties and good thermal conductivity is used, such as, for example, an epoxy resin containing any of BN, SiO₂, Si₃N₄, Al₂O₃, and AlN as a filler.

In the semiconductor device 101, each structure is sealed with the sealing resin 70 having a quadrangular plan view shape. Specifically, the sealing resin 70 seals the first die pad 11, the second die pad 12, the third die pad 51, the first semiconductor element 21, the second semiconductor element 22, the control integrated circuit 52, the first wire 31, the second wire 32, the third wire 33, the fourth wire 34, the fifth wire 53, a part of the first main terminal 41, a part of the second main terminal 42, a part of the output terminal 43, a part of the control terminal 54, and a part of the insulating sheet 60. That is, a part of the first main terminal 41, a part of the second main terminal 42, a part of the output terminal 43, a part of the control terminal 54, and at least a part of the lower surface of the insulating sheet 60 are exposed to the outside of the sealing resin 70.

With the above configuration, heat generated by the first semiconductor element 21 and the second semiconductor element 22 is released to the outside of the semiconductor device 101 via the insulating sheet 60 and via the first die pad 11 and the second die pad 12 respectively in contact with the first semiconductor element 21 and the second semiconductor element 22.

Note that the semiconductor device 101 may include a heat dissipation plate (not illustrated). The heat dissipation plate is arranged on the lower surface of the insulating sheet 60. By further providing the heat dissipation plate, it is possible to improve heat dissipation of heat generated by the first semiconductor element 21 and the second semiconductor element.

As described above, the semiconductor device 101 has a configuration in which the three first semiconductor elements 21, the three second semiconductor elements 22, and the three control integrated circuits 52 for controlling the first semiconductor element 21 and the second semiconductor element 22 are mounted in one package. The semiconductor device 101 includes a three-phase inverter circuit including the three first semiconductor elements 21 and the three second semiconductor elements 22, and a drive circuit including the three control integrated circuits 52. Here, a circuit configuration of the semiconductor device 101 will be described.

The three-phase inverter circuit included in the semiconductor device 101 is a circuit that converts DC power into three-phase AC power and outputs the three-phase AC power, through the switching operation of the first semiconductor element 21 and the second semiconductor element 22. The three-phase inverter circuit is formed such that the first semiconductor element 21 on the high potential side and the second semiconductor element 22 on the low potential side are electrically connected between the first main terminal 41 connected to an external substrate (not illustrated) on the high potential side and the second main terminal 42 connected to an external substrate (not illustrated) on the low potential side, and a connection node connecting output sides of AC power of the two is to be the output terminal 43. That is, in order to form the three-phase inverter circuit, the first semiconductor element 21 on the high potential side and the second semiconductor element 22 on the low potential side need to be electrically connected. In addition, the three first semiconductor elements 21 need to be electrically connected in parallel. Similarly, the three second semiconductor elements 22 need to be electrically connected in parallel.

As described above, three first semiconductor elements 21 and three second semiconductor elements 22 are provided corresponding to three phases. That is, one first semiconductor element 21 and one second semiconductor element 22 are provided for each phase, and three first semiconductor elements 21 and three second semiconductor elements 22 are provided for three phases. Three output terminals 43 are provided individually corresponding to the three phases.

The drive circuit included in the semiconductor device 101 is a circuit that controls the switching operation of the first semiconductor element 21 and the second semiconductor element 22. The drive circuit is formed such that one control integrated circuit 52 controls the switching operation for a set of the first semiconductor element 21 and the second semiconductor element 22 constituting one phase among the three phases. That is, one control integrated circuit 52 is provided for each phase, and three control integrated circuits 52 are provided for three phases.

As described above, by using the three-phase inverter circuit and the drive circuit, the semiconductor device 101 controls the switching operation of the three first semiconductor elements 21 and the three second semiconductor elements 22, converts DC power into three-phase AC power, and outputs the three-phase AC power.

Although the example has been described in which the semiconductor device 101 includes three first semiconductor elements 21 and three second semiconductor elements 22, the semiconductor device 101 may include three or more first semiconductor elements 21 and more than three second semiconductor elements 22. It suffices that the semiconductor device 101 includes at least three first semiconductor elements 21 and at least three second semiconductor elements 22. For example, a three-phase voltage-type three-level inverter circuit may be formed by including six first semiconductor elements 21 and six second semiconductor elements 22. More than three first die pads 11 and three or more second die pads 12 may be provided according to the number of first semiconductor elements 21 and second semiconductor elements 22.

### Method of Manufacturing First Preferred Embodiment

Next, a method of manufacturing the semiconductor device 101 according to the first preferred embodiment of the present disclosure will be described. Note that, in the present preferred embodiment, among processes of manufacturing the semiconductor device 101, processes other than a process of forming the three first die pads 11 can be implemented by appropriately applying a known technology, and thus only the process of forming the three first die pads 11 will be described here.

The three first die pads 11 are formed by punching a copper plate having conductivity and good thermal conductivity. The three first die pads 11 are formed by, for example, punching the copper plate into a predetermined shape using a mold.

### Action and Effect of First Preferred Embodiment

Next, action and effect of the semiconductor device 101 according to the first preferred embodiment of the present disclosure will be described by comparing a conventional semiconductor device and the semiconductor device 101 of the present disclosure.

In the conventional semiconductor device, for example, in the device of Japanese Patent Application Laid-Open No. 2009-111154, three sets of the IGBT chip and the freewheel diode on the high potential side are mounted on one die pad portion. Therefore, the device of Japanese Patent Application Laid-Open No. 2009-111154 has a configuration in which the semiconductor element on the high potential side and the semiconductor element on the low potential side, which need to be electrically connected to each other to form the three-phase inverter circuit, are arranged at positions separated from each other.

In order to connect the semiconductor element on the high potential side and the semiconductor element on the low potential side, a terminal extending from a die pad mounted with the semiconductor element on the low potential side is formed in a shape having one or more bent portions.

Therefore, in the device of Japanese Patent Application Laid-Open No. 2009-111154, an area of the die pad with respect to an area of the entire device has been unable to be enlarged by a space in which the bent portion of the terminal is arranged, and heat dissipation of the semiconductor element has been unable to be improved by increasing the area of the die pad.

The semiconductor device 101 according to the first preferred embodiment of the present disclosure includes: at least three first die pads 11; at least three first semiconductor elements 21 individually mounted on the first die pads 11; the first wire 31 electrically connecting each of the first semiconductor elements 21; at least three second die pads 12 arranged alternately with the first die pads 11; at least three second semiconductor elements 22 individually mounted on the second die pads 12; and the second wire 32 electrically connecting each of the second semiconductor elements 22.

According to the semiconductor device 101 of the first preferred embodiment of the present disclosure, by separating the first die pad 11 mounted with the first semiconductor element 21 corresponding to the semiconductor element on the high potential side into three, and alternately arranging the first die pad 11 and the second die pad 12 mounted with the second semiconductor element 22 corresponding to the semiconductor element on the low potential side, the first semiconductor element 21 and the second semiconductor element 22 which need to be electrically connected to each other can be arranged adjacently. By arranging the first semiconductor element 21 and the second semiconductor element 22 adjacently, it is no longer necessary to bend and arrange the output terminal 43 corresponding to a terminal extending from the second die pad so as to approach in the direction in which the first semiconductor element 21 is present. That is, the first semiconductor element 21 and the second semiconductor element 22 can be electrically connected to each other without the output terminal 43 being bent. Therefore, according to the semiconductor device 101 of the first preferred embodiment of the present disclosure, since the output terminal 43 can be arranged without being bent, an area of the first die pad 11 and the second die pad 12 with respect to an area of the semiconductor device 101 can be enlarged as compared with the conventional semiconductor device by the space in which the bent terminal is arranged in the conventional device.

Heat generated by the first semiconductor element 21 and the second semiconductor element 22 is dissipated to the outside of the semiconductor device 101 via the first die pad 11 and the second die pad 12. Therefore, according to the semiconductor device 101 of the first preferred embodiment of the present disclosure, the area of the first die pad 11 and the second die pad 12 can be enlarged as compared with the conventional semiconductor device, so that heat dissipation of the semiconductor device 101 can be improved as compared with the conventional semiconductor device. Furthermore, according to the semiconductor device 101 of the first preferred embodiment of the present disclosure, by improving heat dissipation of the semiconductor device 101, an energizing current of the semiconductor device 101 can be increased as compared with the conventional semiconductor device.

### Second Preferred Embodiment

In the first preferred embodiment of the present disclosure, a description has been given to the semiconductor device 101 including the first main terminal 41, the second main terminal 42, and the output terminal 43 provided to protrude from the first side surface of the sealing resin 70 including the first side 71 which is a side extending in the direction in which the first die pad 11 and the second die pad 12 are alternately arranged among the sides of the sealing resin 70 in plan view. In a second preferred embodiment of the present disclosure, a description is given to a semiconductor device 102 including: an output terminal 43 provided to protrude from a first side surface of a sealing resin 70; a first main terminal 241 provided to protrude from a second side surface of the sealing resin 70 including a second side 72 which is a side on one end side in a direction in which a first die pad 11 and a second die pad 12 are alternately arranged among sides of the sealing resin 70 in plan view; and a second main terminal 242 provided to protrude from a third side surface of the sealing resin 70 including a third side 73 which is a side on another end side in the direction in which the first die pad 11 and the second die pad 12 are alternately arranged among sides of the sealing resin 70 in plan view.

In the second preferred embodiment, the same components as those in the first preferred embodiment of the present disclosure are denoted by the same reference numerals, and descriptions of the same or corresponding parts are omitted. Hereinafter, the semiconductor device 102 according to the second preferred embodiment will be described with reference to the drawings.

### Configuration of Second Preferred Embodiment

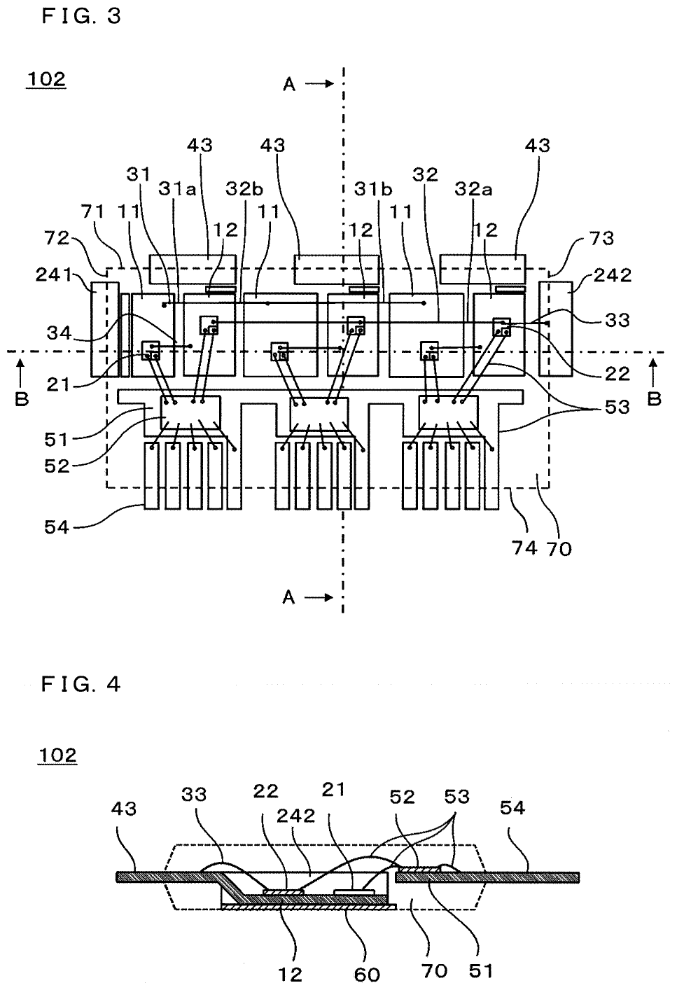

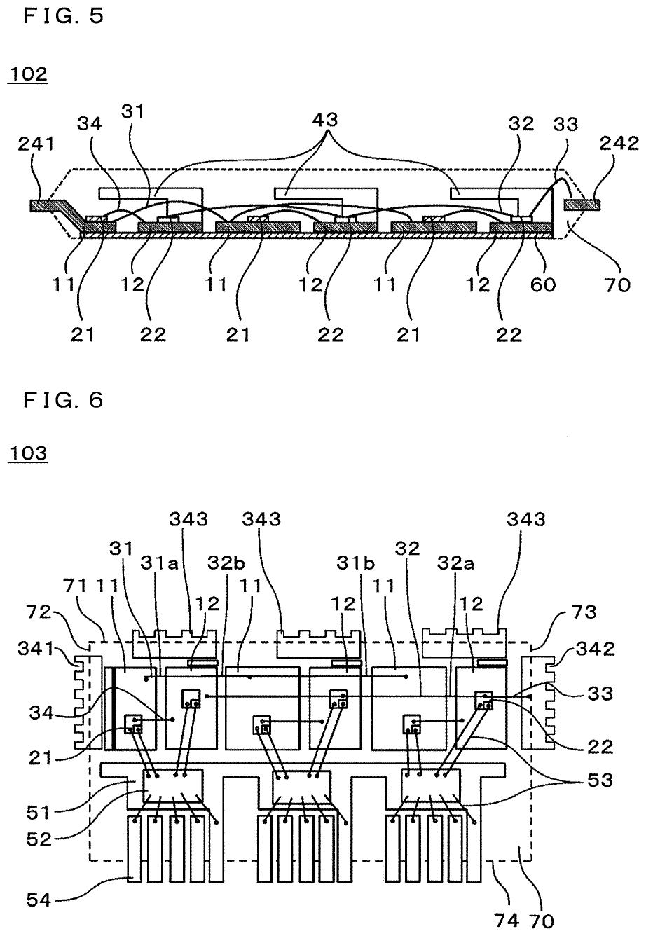

A configuration of the semiconductor device 102 according to the second preferred embodiment of the present disclosure will be described with reference to FIGS. 3, 4, and 5. FIG. 3 is a plan view illustrating the semiconductor device 102. FIG. 4 is a cross-sectional view taken along line A-A in FIG. 3, and FIG. 5 is a cross-sectional view taken along line B-B in FIG. 3. In FIGS. 3, 4, and 5, the sealing resin 70 is omitted to show a structure inside the sealing resin 70. Further, in FIGS. 3, 4, and 5, an outline when the sealing resin 70 is present is indicated by a dotted line.

As illustrated in FIGS. 3, 4, and 5, the semiconductor device 102 includes: the output terminal 43 provided to protrude from the first side surface of the sealing resin 70 including a first side 71 which is a side extending in the direction in which the first die pad 11 and the second die pad 12 are alternately arranged among sides of the sealing resin 70 in plan view; the first main terminal 241 provided to protrude from the second side surface of the sealing resin 70 including the second side 72 which is a side on one end side in the direction in which the first die pad 11 and the second die pad 12 are alternately arranged among sides of the sealing resin 70 in plan view; and the second main terminal 242 provided to protrude from the third side surface of the sealing resin 70 including the third side 73 which is a side on another end side in the direction in which the first die pad 11 and the second die pad 12 are alternately arranged among sides of the sealing resin 70 in plan view.

As described above, by providing the individual terminals to protrude from different side surfaces of the sealing resin 70, the first main terminal 241, the second main terminal 242, and the output terminal 43 are arranged apart from one another.

Note that, in addition to providing the individual terminals to protrude from different side surfaces of the sealing resin 70, an area of a portion protruding from the sealing resin 70 in each terminal may be enlarged. Specifically, as illustrated in FIGS. 3, 4, and 5, the individual terminals may be provided to protrude from different side surfaces of the sealing resin 70, and a width of the portion protruding from the sealing resin 70 in each terminal may be increased in a direction orthogonal to a protruding direction in plan view. A configuration in which the width of the portion protruding from the sealing resin 70 in each terminal is increased will be described with reference to FIGS. 3, 4, and 5.

As illustrated in FIGS. 3, 4, and 5, the first main terminal 241, the second main terminal 242, and the output terminal 43 are provided to protrude from different side surfaces of the sealing resin 70, so that a width in the direction orthogonal to the protruding direction in plan view can be increased at the portion protruding from the sealing resin 70 in each terminal. Specifically, in the direction in which the first die pad 11 and the second die pad 12 are alternately arranged, a width of the portion protruding from the sealing resin 70 in the output terminal 43 is longer than a width of the second die pad 12. In the direction orthogonal to the direction in which the first die pad 11 and the second die pad 12 are alternately arranged, a width of the portion protruding from the sealing resin 70 in the first main terminal 241 is longer than a width of the first die pad 11. In the direction orthogonal to the direction in which the first die pad 11 and the second die pad 12 are alternately arranged, a width of the portion protruding from the sealing resin 70 in the second main terminal 242 is longer than a width of the second die pad 12.

As described above, for each terminal, in the portion protruding from the sealing resin 70 in the terminal, the width in the direction orthogonal to the direction protruding from the side surface of the sealing resin 70 in plan view is increased, whereby an area of each terminal is enlarged.

Although FIG. 3 illustrates an example in which portions protruding from the sealing resin 70 in the first main terminal 241, the second main terminal 242, and the output terminal 43 have a quadrangular plan view shape, the present disclosure is not limited thereto. The portions protruding from the sealing resin 70 in the first main terminal 241, the second main terminal 242, and the output terminal 43 may be, for example, a plate-shaped member having a polygonal shape or a rounded shape.

### Method of Manufacturing Second Preferred Embodiment

Since a method of manufacturing the semiconductor device 102 according to the second preferred embodiment of the present disclosure is similar to the method of manufacturing the semiconductor device 101 according to the first preferred embodiment, the description thereof will be omitted.

### Action and Effect of Second Preferred Embodiment

Next, action and effect of the semiconductor device 102 according to the second preferred embodiment of the present disclosure will be described.

The semiconductor device 102 according to the second preferred embodiment of the present disclosure includes: the output terminal 43 provided to protrude from the first side surface of the sealing resin 70 including the first side 71 which is a side extending in the direction in which the first die pad 11 and the second die pad 12 are alternately arranged among sides in plan view of the sealing resin 70 having a quadrangular plan view shape; the first main terminal 241 provided to protrude from the second side surface of the sealing resin 70 including the second side 72 which is a side on one end side in the direction in which the first die pad 11 and the second die pad 12 are alternately arranged among sides of the sealing resin 70 in plan view; and the second main terminal 242 provided to protrude from the third side surface of the sealing resin 70 including the third side 73 which is a side on another end side in the direction in which the first die pad 11 and the second die pad 12 are alternately arranged among sides of the sealing resin 70 in plan view.

According to the semiconductor device 102 of the second preferred embodiment of the present disclosure, the first main terminal 241, the second main terminal 242, and the output terminal 43 are provided to respectively protrude from the second side surface, the third side surface, and the first side surface, which are different side surfaces of the sealing resin 70. Therefore, the first main terminal 241, the second main terminal 242, and the output terminal 43 are arranged away from one another, and a creepage distance between the terminals can be reliably secured.

Furthermore, in the semiconductor device 102 according to the second preferred embodiment of the present disclosure, in the direction in which the first die pad 11 and the second die pad 12 are alternately arranged, the width of the portion protruding from the sealing resin 70 in the output terminal 43 is longer than the width of the second die pad 12. In the direction orthogonal to the direction in which the first die pad 11 and the second die pad 12 are alternately arranged, the width of the portion protruding from the sealing resin 70 in the first main terminal 241 is longer than the width of the first die pad 11. In the direction orthogonal to the direction in which the first die pad 11 and the second die pad 12 are alternately arranged, a width of a portion protruding from the sealing resin 70 in the second main terminal 242 is longer than the width of the second die pad 12.

As described above, according to the semiconductor device 102 of the second preferred embodiment of the present disclosure, it is possible to enlarge the areas of the first main terminal 241, the second main terminal 242, and the output terminal 43 with respect to the area of the semiconductor device 102 as compared with the first preferred embodiment, while reliably securing a creepage distance between the terminals. Heat generated by a first semiconductor element 21 and a second semiconductor element 22 is dissipated to the outside of the semiconductor device 102 via the first main terminal 241, the second main terminal 242, and the output terminal 43. Therefore, according to the semiconductor device 102 of the second preferred embodiment of the present disclosure, by enlarging the areas of the first main terminal 241, the second main terminal 242, and the output terminal 43, heat dissipation of the semiconductor device 102 can be further improved. In addition, according to the semiconductor device 102 of the second preferred embodiment of the present disclosure, it is possible to further increase an energizing current of the semiconductor device 102 by improving heat dissipation of the semiconductor device 102.

### Third Preferred Embodiment

In the second preferred embodiment of the present disclosure, a description has been given to the semiconductor device 102 including: the output terminal 43 provided to protrude from the first side surface of the sealing resin 70; the first main terminal 241 provided to protrude from the second side surface of the sealing resin 70; and the second main terminal 242 provided to protrude from the third side surface of the sealing resin 70. In a third preferred embodiment of the present disclosure, a description is given to a semiconductor device 103 including a first main terminal 341, a second main terminal 342, and an output terminal 343, in which at least a part of a portion protruding from a sealing resin 70 is formed in a comb shape.

In the third preferred embodiment, the same components as those in the first and second preferred embodiments of the present disclosure are denoted by the same reference numerals, and descriptions of the same or corresponding parts are omitted. Hereinafter, the semiconductor device 103 according to the third preferred embodiment will be described with reference to the drawings.

### Configuration of Third Preferred Embodiment

A configuration of the semiconductor device 103 according to the third preferred embodiment of the present disclosure will be described with reference to FIG. 6. FIG. 6 is a plan view illustrating the semiconductor device 103. In FIG. 6, the sealing resin 70 is omitted in order to show a structure inside the sealing resin 70. In FIG. 6, an outline when the sealing resin 70 is present is indicated by a dotted line.

As illustrated in FIG. 6, the semiconductor device 103 includes the first main terminal 341, the second main terminal 342, and the output terminal 343, in which a part of a portion protruding from the sealing resin 70 is formed in a comb shape. For example, as illustrated in FIG. 6, a portion protruding from the sealing resin 70 in each of the first main terminal 341, the second main terminal 342, and the output terminal 343 is a polygon having one side formed in a comb shape in plan view. That is, the portions protruding from the sealing resin 70 in the first main terminal 341, the second main terminal 342, and the output terminal 343 have a quadrangular plan view shape before being formed in a comb shape, and are formed by forming one side in a comb shape in a plate-shaped member having a quadrangular plan view shape.

It suffices to form a part of the portions protruding from the sealing resin 70 in a comb shape in the first main terminal 341, the second main terminal 342, and the output terminal 343. The first main terminal 341, the second main terminal 342, and the output terminal 343 are not limited to those in which one side of the plate-shaped member having the quadrangular plan view shape at the portion protruding from the sealing resin 70 is entirely formed in a comb shape, and may be those in which one side is partially formed in a comb shape. Further, the first main terminal 341, the second main terminal 342, and the output terminal 343 may be formed by forming two or more sides of the plate-shaped member having the quadrangular plan view shape into a comb shape at the portion protruding from the sealing resin 70. Further, in the first main terminal 341, the second main terminal 342, and the output terminal 343, the portion protruding from the sealing resin 70 before being formed in a comb shape may not have a quadrangular plan view shape, and a part of the portion protruding from the sealing resin 70 may be formed in a comb shape in a plate-shaped member having a polygonal or rounded shape.

FIG. 6 illustrates an example in which the first main terminal 341, the second main terminal 342, and the output terminal 343 in which a part of a portion protruding from the sealing resin 70 is formed in a comb shape respectively protrude from the second side surface, the third side surface, and the first side surface of the sealing resin 70, similarly to the second preferred embodiment. Without limiting to this, the first main terminal 341, the second main terminal 342, and the output terminal 343 in which a part of a portion protruding from the sealing resin 70 is formed in a comb shape may be provided to protrude from the first side surface similarly to the first preferred embodiment, for example.

As described above, since a part of a portion protruding from the sealing resin 70 in each terminal is formed in a comb shape, an area where each terminal comes into contact with an external substrate or external air (not illustrated) is enlarged.

### Method of Manufacturing Third Preferred Embodiment

Next, a method of manufacturing the semiconductor device 103 according to the third preferred embodiment of the present disclosure will be described. Note that, in the present preferred embodiment, among processes of manufacturing the semiconductor device 103, processes other than a process of forming the first main terminal 341, the second main terminal 342, and the output terminal 343 can be implemented by appropriately applying a known technology. Therefore, here, only the process of forming the first main terminal 341, the second main terminal 342, and the output terminal 343 will be described.

The first main terminal 341, the second main terminal 342, and the output terminal 343 are formed by punching a copper plate having conductivity and good thermal conductivity. The first main terminal 341, the second main terminal 342, and the output terminal 343 are formed by, for example, punching the copper plate into a predetermined shape using a mold. Here, the predetermined shape is, for example, a polygonal shape having one side formed in a comb shape.

### Action and Effect of Third Preferred Embodiment

Next, action and effect of the semiconductor device 103 according to the third preferred embodiment of the present disclosure will be described.

The semiconductor device 103 according to the third preferred embodiment of the present disclosure includes the first main terminal 341, the second main terminal 342, and the output terminal 343, in which a part of a portion protruding from the sealing resin 70 is formed in a comb shape.

According to the semiconductor device 103 of the third preferred embodiment of the present disclosure, at least a part of a portion protruding from the sealing resin 70 is formed in a comb shape in the first main terminal 341, the second main terminal 342, and the output terminal 343. Therefore, an area where each of the first main terminal 341, the second main terminal 342, and the output terminal 343 is in contact with an external substrate or external air (not illustrated) can be enlarged as compared with the first and second preferred embodiments. Heat generated by a first semiconductor element 21 and a second semiconductor element 22 is transferred to an external substrate (not illustrated) or external air via the first main terminal 341, the second main terminal 342, and the output terminal 343, to be dissipated to the outside of the semiconductor device 103. Therefore, according to the semiconductor device 103 of the third preferred embodiment of the present disclosure, heat dissipation of the semiconductor device 103 can be further improved by providing the first main terminal 341, the second main terminal 342, and the output terminal 343 in which at least a part of a portion protruding from the sealing resin 70 is formed in a comb shape. In addition, according to the semiconductor device 103 of the third preferred embodiment of the present disclosure, it is possible to further increase an energizing current of the semiconductor device 103 by improving heat dissipation of the semiconductor device 103.

### Fourth Preferred Embodiment

In the first preferred embodiment of the present disclosure, the semiconductor device 101 including the first wire 31, the second wire 32, and the third wire 33 has been described. In a fourth preferred embodiment of the present disclosure, a semiconductor device 104 will be described in which the number of wires through which a current flows frequently is two or more in a first wire 31, a second wire 32, and a third wire 33.

### Configuration of Fourth Preferred Embodiment

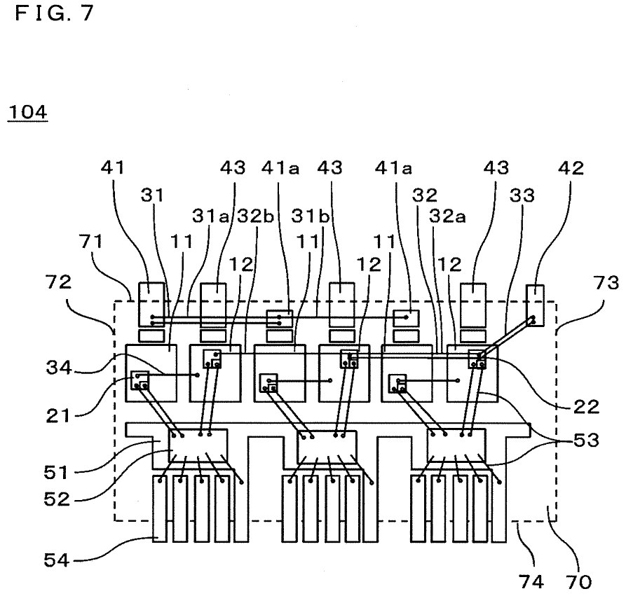

A configuration of the semiconductor device 104 according to the fourth preferred embodiment of the present disclosure will be described with reference to FIG. 7. FIG. 7 is a plan view illustrating the semiconductor device 104. In FIG. 7, a sealing resin 70 is omitted in order to show a structure inside the sealing resin 70. In FIG. 7, an outline when the sealing resin 70 is present is indicated by a dotted line.

As illustrated in FIG. 7, in the semiconductor device 104, the number of wires is two or more in: in the first wire 31, a first wire 31a provided to connect between two first die pads 11 on one end side in a direction in which the first die pad 11 and a second die pad 12 are alternately arranged; in the second wire 32, a second wire 32a provided to connect between two second semiconductor elements 22 on another end side in the direction in which the first die pad 11 and the second die pad 12 are alternately arranged; and the third wire 33.

The first wire 31a, the second wire 32a, and the third wire 33 are wires through which a current frequently flows, as compared with a first wire 31b provided to connect between two first die pads 11 on another end side in the direction in which the first die pad 11 and the second die pad 12 are alternately arranged, and a second wire 32b provided to connect between two second semiconductor elements 22 on one end side in the direction in which the first die pad 11 and the second die pad 12 are alternately arranged. Therefore, by increasing the number of the first wires 31a, the second wires 32a, and the third wires 33, it is possible to reduce a density of the current flowing through one wire, and to reduce a load due to the current.

### Method of Manufacturing Fourth Preferred Embodiment

Since a method of manufacturing the semiconductor device 104 according to the fourth preferred embodiment of the present disclosure is similar to the method of manufacturing the semiconductor device 101 according to the first preferred embodiment, the description thereof will be omitted.

### Action and Effect of Fourth Preferred Embodiment

Next, action and effect of the semiconductor device 104 according to the fourth preferred embodiment of the present disclosure will be described.

In the semiconductor device 104 according to the fourth preferred embodiment of the present disclosure, the number of wires is two or more in: in the first wire 31, the first wire 31a provided to connect between two first die pads 11 on one end side in the direction in which the first die pad 11 and the second die pad 12 are alternately arranged; in the second wire 32, the second wire 32a provided to connect between two second semiconductor elements 22 on another end side in the direction in which the first die pad 11 and the second die pad 12 are alternately arranged; and the third wire 33.

According to the semiconductor device 104 of the fourth preferred embodiment of the present disclosure, it is possible to reduce a density of a current flowing through the first wire 31a, the second wire 32a, and the third wire 33, which are wires through which a current frequently flow, and to reduce the load due to the current flowing through each wire. Therefore, according to the semiconductor device 104 of the fourth preferred embodiment of the present disclosure, by reducing the load due to the current flowing through each wire, deterioration of the wire can be suppressed, and power cycle life of the semiconductor device 104 can be improved.

### Fifth Preferred Embodiment

In the fourth preferred embodiment of the present disclosure, a description has been given to the semiconductor device 104 in which the number of wires is two or more in the first wires 31a, the second wires 32a, and the third wires 33, which are wires through which a current frequently flows. In a fifth preferred embodiment of the present disclosure, a semiconductor device 105 will be described in which wire diameters of a first wire 31a, a second wire 32a, and a third wire 33 are increased.

### Configuration of Fifth Preferred Embodiment

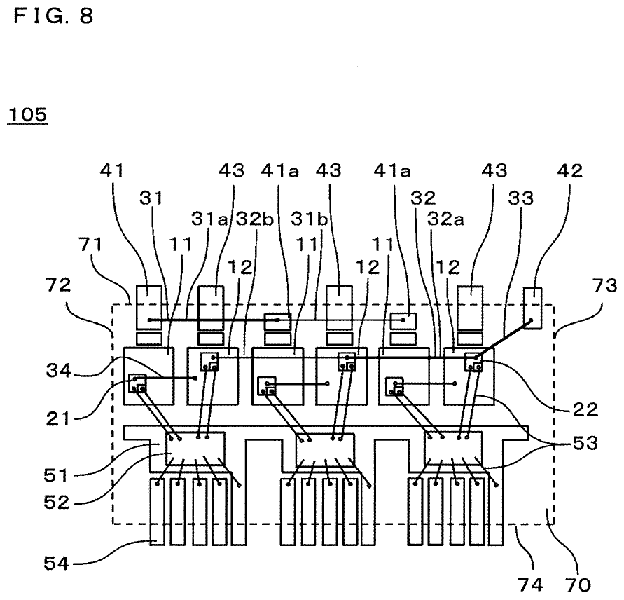

A configuration of the semiconductor device 105 according to the fifth preferred embodiment of the present disclosure will be described with reference to FIG. 8. FIG. 8 is a plan view illustrating the semiconductor device 105. In FIG. 8, a sealing resin 70 is omitted in order to show a structure inside the sealing resin 70. In FIG. 8, an outline when the sealing resin 70 is present is indicated by a dotted line.

As illustrated in FIG. 8, in the semiconductor device 105, a wire diameter is large in: in first wire 31, the first wire 31a provided to connect between two first die pads 11 on one end side in the direction in which the first die pad 11 and a second die pad 12 are alternately arranged; in second wire 32, the second wire 32a provided to connect between two second semiconductor elements 22 on another end side in the direction in which the first die pad 11 and the second die pad 12 are alternately arranged; and the third wire 33, as compared with: a first wire 31b provided to connect between two first die pads 11 on another end side in the direction in which the first die pad 11 and the second die pad 12 are alternately arranged; and a second wire 32b provided to connect between two second semiconductor elements 22 on one end side in the direction in which the first die pad 11 and the second die pad 12 are alternately arranged.

As described in the fourth preferred embodiment, the first wire 31a, the second wire 32a, and the third wire 33 are wires through which a current flows more frequently than the first wire 31b and the second wire 32b. Therefore, by increasing the wire diameters of the first wire 31a, the second wire 32a, and the third wire 33, a density of a current flowing through the wire can be reduced, and a load due to the current is reduced.

### Method of Manufacturing Fifth Preferred Embodiment

Since a method of manufacturing the semiconductor device 105 according to the fifth preferred embodiment of the present disclosure is similar to the method of manufacturing the semiconductor device 101 according to the first preferred embodiment, the description thereof will be omitted.

### Action and Effect of Fifth Preferred Embodiment

Next, action and effect of the semiconductor device 105 according to the fifth preferred embodiment of the present disclosure will be described.

In the semiconductor device 105 according to the fifth preferred embodiment of the present disclosure, a wire diameter is large in: in the first wire 31, the first wire 31a provided to connect between two first die pads 11 on one end side in the direction in which the first die pad 11 and the second die pad 12 are alternately arranged; in the second wire 32, the second wire 32a provided to connect between two second semiconductor elements 22 on another end side in the direction in which the first die pad 11 and the second die pad 12 are alternately arranged; and the third wire 33, as compared with: the first wire 31b provided to connect between two first die pads 11 on another end side in the direction in which the first die pad 11 and the second die pad 12 are alternately arranged; and the second wire 32b provided to connect between two second semiconductor elements 22 on one end side in the direction in which the first die pad 11 and the second die pad 12 are alternately arranged.

According to the semiconductor device 105 of the fifth preferred embodiment of the present disclosure, it is possible to reduce a density of a current flowing through the first wire 31a, the second wire 32a, and the third wire 33, which are wires through which a current frequently flow, and to reduce the load due to the current flowing through each wire. Therefore, according to the semiconductor device 105 of the fifth preferred embodiment of the present disclosure, by reducing the load due to the current flowing through each wire, deterioration of the wire can be suppressed, and power cycle life of the semiconductor device 105 can be improved.

Although the present disclosure has been described above based on each preferred embodiment, the present disclosure is not limited to each preferred embodiment. In addition, appropriately combining, modifying, or omitting each preferred embodiment is also included in the scope of the technical idea of the present disclosure.

These and other objects, features, aspects and advantages of the present disclosure will become more apparent from the following detailed description of the present disclosure when taken in conjunction with the accompanying drawings.

What is claimed is:

1. A semiconductor device comprising:
at least three first die pads;
at least three first semiconductor elements individually mounted on the first die pads;
a first wire electrically connecting each of the first semiconductor elements;
at least three second die pads arranged alternately with the first die pads;
at least three second semiconductor elements individually mounted on the second die pads; and
a second wire electrically connecting each of the second semiconductor elements.

2. The semiconductor device according to claim 1, further comprising:
a first main terminal extending from a first die pad among the first die pads, the first die pad being arranged on one end side in a direction in which the first die pads and the second die pads are alternately arranged;
a second main terminal arranged on another end side in the direction in which the first die pads and the second die pads are alternately arranged;
at least three output terminals extending from at least three of the second die pads; and
a sealing resin configured to seal the first die pads, the second die pads, the first semiconductor elements, the second semiconductor elements, the first wire, the second wire, a part of the first main terminal, a part of the second main terminal, and a part of each of the output terminals.

3. The semiconductor device according to claim 2, wherein
the sealing resin has a quadrangular plan view shape, and
the first main terminal, the second main terminal, and the output terminals are provided to protrude from a first side surface including a first side in the sealing resin, the first side being a side extending in the direction in which the first die pads and the second die pads are alternately arranged among sides of the sealing resin in plan view.

4. The semiconductor device according to claim 2, wherein
the sealing resin has a quadrangular plan view shape,
the output terminals are provided to protrude from a first side surface including a first side in the sealing resin, the first side being a side extending in the direction in which the first die pads and the second die pads are alternately arranged among sides of the sealing resin in plan view,
the first main terminal is provided to protrude from a second side surface including a second side in the sealing resin, the second side being a side on the one end side in the direction in which the first die pads and the second die pads are alternately arranged among sides of the sealing resin in plan view, and
the second main terminal is provided to protrude from a third side surface including a third side in the sealing resin, the third side being a side on the another end side in the direction in which the first die pads and the second die pads are alternately arranged among sides of the sealing resin in plan view.

5. The semiconductor device according to claim 4, wherein
in the direction in which the first die pads and the second die pads are alternately arranged, a width of a portion protruding from the sealing resin in each of the output terminals is longer than a width of each of the second die pads,
in a direction orthogonal to the direction in which the first die pads and the second die pads are alternately arranged, a width of a portion protruding from the sealing resin in the first main terminal is longer than a width of each of the first die pads, and
in a direction orthogonal to the direction in which the first die pads and the second die pads are alternately arranged, a width of a portion protruding from the sealing resin in the second main terminal is longer than a width of each of the second die pads.

6. The semiconductor device according to claim 2, wherein in the first main terminal, the second main terminal, and the output terminals, at least a part of a portion protruding from the sealing resin is formed in a comb shape.

7. The semiconductor device according to claim 2, further comprising a third wire electrically connecting the second main terminal with a second semiconductor element among the second semiconductor elements, wherein
the first wire is provided to connect between two of the first die pads adjacent to each other with one of the second die pads interposed between the two of the first die pads,
the second wire is provided to connect between two of the second semiconductor elements individually mounted on two of the second die pads adjacent to each other with one of the first die pads interposed between the two of the second die pads, and
the third wire is provided to connect between the second semiconductor element and the second main terminal, the second semiconductor element being mounted on a second die pad among the second die pads, the second die pad being arranged on the another end side in the direction in which the first die pads and the second die pads are alternately arranged.

8. The semiconductor device according to claim 7, wherein a number of wires is two or more in: in the first wire, the first wire provided to connect between two of the first die pads on the one end side in the direction in which the first die pads and the second die pads are alternately arranged; in the second wire, the second wire provided to connect between two of the second semiconductor elements on the another end side in the direction in which the first die pads and the second die pads are alternately arranged; and the third wire.

9. The semiconductor device according to claim 7, wherein a wire diameter is large in: in the first wire, the first wire provided to connect between two of the first die pads on the one end side in the direction in which the first die pads and the second die pads are alternately arranged; in the second wire, the second wire provided to connect between two of the second semiconductor elements on the another end side in the direction in which the first die pads and the second die pads are alternately arranged; and the third wire, as compared with a wire diameter of the first wire provided to connect between two of the first die pads on the another end side; and the second wire provided to connect between two of the second semiconductor elements on the one end side.
